(19) United States
(12) Patent Application Publication
(10) Pub. No.: US 2005/0236622 A1
(43) Pub. Date: Oct. 27, 2005

(54) Electronic device and method of manufacturing the same

(75) Inventors: Ji-sim Jung, Incheon-si (KR); Takashi Noguchi, Gyeonggi-do (KR); Hans S. Cho, Seoul (KR); Do-young Kim, Gyeonggi-do (KR); Kyung-bae Park, Seoul (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG ELECTRONICS CO., LTD., Gyeonggi-do (KR)

(21) Appl. No.: 11/100,476

(22) Filed: Apr. 7, 2005

(30) Foreign Application Priority Data
Apr. 8, 2004 (KR) 10-2004-0024010

(51) Int. Cl. H01L 29/786; H01L 21/84

(52) U.S. Cl. 257/66; 438/166; 438/487; 257/75

(57) ABSTRACT

Provided are an electronic device and a method of manufacturing the same. The device includes a plastic substrate, a transparent thermal conductive layer stacked on the plastic substrate, a polysilicon layer stacked on the thermal conductive layer; and a functional device disposed on the polysilicon layer. The functional device is any one of a transistor, a light emitting device, and a memory device. The functional device may be a thin film transistor including a gate stack stacked on the polysilicon layer.

### BACKGROUND OF THE INVENTION

Priority is claimed to Korean Patent Application No. 10-2004-0024010, filed on Apr. 8, 2004 in the Korean Intellectual Property Office, the disclosure of which is incorporated herein in its entirety by reference.

1. Field of the Invention

The present invention relates to an electronic device and a method of manufacturing the same.

2. Description of the Related Art

A flat panel display (FPD), such as an organic light emitting diode (OLED) display or a liquid crystal display (LCD), employs a thin film transistor (TFT) as a switching device. A channel region of the TFT can be formed of amorphous silicon (a-Si) or polysilicon.

If the channel region of the TFT is formed of a-Si, a uniform layer can be formed at a relatively low temperature. However, the channel region cannot operate at high speed due to low carrier mobility.

If the channel region of the TFT is formed of polysilicon, carrier mobility can be increased in comparison with a channel region formed of a-Si.

To form a polysilicon channel region, a polysilicon layer may be directly deposited. Alternatively, a-Si may be deposited and then crystallized into polysilicon. The crystallization method can be categorized into eximer laser annealing (ELA) or solid phase crystallization (SPC). Nowadays, the ELA has become strongly relied upon since it enables low-temperature formation of good polysilicon having a lower thermal budget and higher field effect mobility as compared with the SPC.

Conventionally, a silicon oxide layer as a buffer layer is formed on a glass substrate or a silicon substrate, and a polysilicon layer is formed by crystallizing a-Si using ELA.

A semiconductor device, in which a TFT is formed on a plastic substrate instead of a glass substrate or a silicon substrate, is disclosed in U.S. Pat. No. 5,817,550. In this device, an a-Si layer is deposited on a SiO₂ buffer layer using radio frequency (RF) sputtering and then crystallized into polysilicon by ELA.

However, the foregoing crystallization methods cause agglomeration of polycrystalline grains, voids produced between the polycrystalline grains, and a poor surface roughness. Presumably, this is because heat caused by ELA is not exhausted due to a low thermal conductive plastic substrate and a SiO₂ buffer layer to generate local thermal reactions.

### SUMMARY OF THE INVENTION

Embodiments of the present invention provide an electronic device including a polysilicon layer consisting of improved uniformity of polycrystalline grains, which is acquired by interposing a high thermal conductive layer between a plastic substrate and an amorphous silicon layer so as to facilitate heat exhaust during crystallization of the amorphous silicon.

According to an aspect of the present invention, there is provided an electronic device comprising a plastic substrate; a transparent thermal conductive layer stacked on the plastic substrate; a polysilicon layer stacked on the thermal conductive layer; and a functional device disposed on the polysilicon layer.

The functional device may be any one of a transistor, a light emitting device, and a memory device.

The functional device may be a thin film transistor including a gate stack stacked on the polysilicon layer.

The electronic device may further comprise a buffer layer disposed between the thermal conductive layer and the polysilicon layer.

The thermal conductive layer may be formed of aluminum nitride (AlN).

According to another aspect of the present invention, there is provided an electronic device comprising a plastic substrate; a transparent thermal conductive layer stacked on the plastic substrate; a functional device disposed over the thermal conductive layer; and a polysilicon layer disposed on the functional device.

The functional device may be a thin film transistor including a gate electrode disposed on the thermal conductive layer; and a gate oxide layer disposed on the thermal conductive layer to cover the gate electrode.

The electronic device may further comprise a buffer layer disposed between the thermal conductive layer and the gate electrode.

According to still another aspect of the present invention, there is provided a method of manufacturing an electrode device. The method comprises forming a transparent thermal conductive layer on a plastic substrate; forming an amorphous silicon layer on the thermal conductive layer; transforming the amorphous silicon layer into a polysilicon layer; and forming a functional device on the polysilicon layer.

The functional device may be any one of a transistor, a light emitting device, and a memory device.

The functional device may be the thin film transistor, and the forming of the functional device may comprise forming a gate stack on the polysilicon layer.

The method may further comprise forming a buffer layer disposed between the thermal conductive layer and the polysilicon layer.

The transforming of the amorphous silicon layer into the polysilicon layer may be performed by irradiating a laser beam having a predetermined energy density onto the amorphous silicon layer.

According to yet another aspect of the present invention there is provided a method of manufacturing an electronic device. The method comprises forming a transparent thermal conductive layer on a plastic substrate; forming a functional device on the thermal conductive layer; forming an amorphous silicon layer over the functional device; and transforming the amorphous silicon layer into a polysilicon layer.

The functional device may be the thin film transistor. The forming of the functional device may comprise forming a gate electrode on the thermal conductive layer; patterning the gate electrode; and forming a gate insulating layer on the thermal conductive layer to cover the patterned gate electrode, and the forming of the amorphous silicon layer may comprise forming the amorphous layer on the gate insulating layer.

### BRIEF DESCRIPTION OF THE DRAWINGS

The above features and advantages of the present invention will become more apparent by describing in detail exemplary embodiments thereof with reference to the attached drawings in which:

FIG. 1 is a cross-sectional view of a top gate type thin film transistor (TFT) according to an embodiment of the present invention;

FIG. 2 is a cross-sectional view of a bottom gate type TFT according to another embodiment of the present invention;

FIGS. 3 through 6 are cross-sectional views illustrating a method of manufacturing the TFT shown in FIG. 1;

FIG. 7 is a scanning electron microscope (SEM) photograph showing crystalline grains of a polysilicon layer that is formed by one-shot irradiation of an eximer laser beam having an energy density of about 140 mJ/cm² onto an amorphous silicon layer; and

FIGS. 8 through 12 are cross-sectional views illustrating a method of manufacturing the TFT shown in FIG. 2.

### DETAILED DESCRIPTION OF THE INVENTION

The present invention will now be described more fully with reference to the accompanying drawings, in which exemplary embodiments of the invention are shown. The thicknesses of layers or regions in the drawings are exaggerated for clarity. The same reference numerals are used to denote the same elements throughout the drawings.

At the outset, a thin film transistor (TFT) according to embodiments of the present invention will be described.

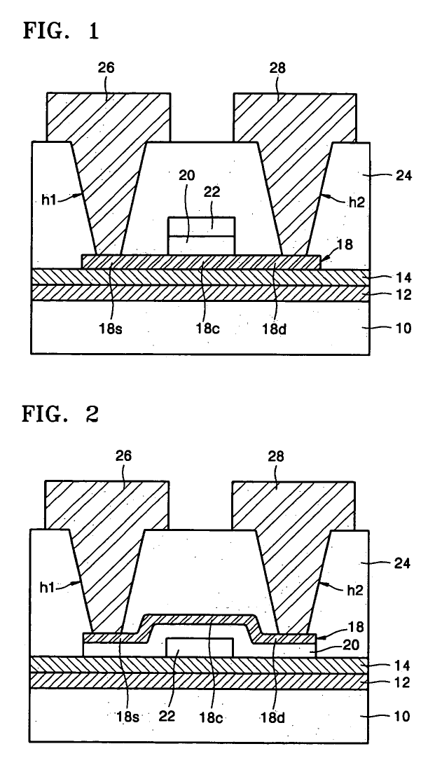

FIG. 1 is a cross-sectional view of a top gate type TFT according to an embodiment of the present invention.

Referring to FIG. 1, a thermal conductive layer 12 and a buffer layer 14 are sequentially stacked on a substrate 10. The thermal conductive layer 12 has a predetermined thickness of, for example, about 1000 Å, and a high thermal conductivity. The buffer layer 14 has a predetermined thickness of 2000 Å. The substrate 10 is a plastic substrate.

If the thermal conductive layer 12 is an insulating layer formed of aluminium nitride (AlN), the buffer layer 14 may be omitted. The thermal conductive layer 12 formed of AlN may serve as the buffer layer 14. Also, when a flat panel display (FPD) uses an AlN layer, which is transparent, it may be used as a reflection or projection type display.

Alternatively, the thermal conductive layer 12 may be formed of a conductive material such as a metal, for example, Al, Cu, Co, or Ni. On top of this thermal conductive layer 12, the buffer layer 14 formed of an insulating material is required.

The buffer layer 14 serves to prevent impurities contained in the substrate 10 from being diffused into members formed on the buffer layer 14 during manufacture of TFTs and improve bonding of a polysilicon layer 18 with the substrate 10.

On top of the buffer layer 14, the polysilicon layer 18 is formed. The polysilicon layer 18 includes a source region 18s, a drain region 18d, and a channel region 18c therebetween. A gate insulating layer 20 and a gate electrode 22 are sequentially stacked on the channel region 18c.

The buffer layer 14, the polysilicon layer 18, the gate electrode 22, and the gate insulating layer 20 are covered by an interlayer dielectric (ILD). A first contact hole h1 and a second contact hole h2 are formed in the ILD 24 so as to expose the source region 18s and the drain region 18d, respectively. A first electrode 26 and a second electrode 28 are formed on the ILD 24 so as to fill the first contact hole h1 and the second contact hole h2, respectively. The first electrode 26 and the second electrode 28 can be formed of the same material.

FIG. 2 is a cross-sectional view of a bottom gate type TFT according to another embodiment of the present invention. In FIG. 2, a gate electrode is disposed under a channel region, and the same reference numerals are used to denote the substantially same elements as in the previous embodiment.

Referring to FIG. 2, a thermal conductive layer 12 and a buffer layer 14 are sequentially stacked on a substrate 10. The thermal conductive layer 12 has a predetermined thickness of, for example, about 1000 Å, and a high thermal conductivity. The buffer layer 14 has a predetermined thickness of, for example, about 2000 Å. The substrate 10 is a plastic substrate.

On top of the buffer layer 14, a gate electrode 22 is formed. Also, a gate insulating layer 20 is formed on the buffer layer 14 so as to cover the gate electrode 22.

A polysilicon layer 18 is disposed on the gate insulating layer 20. The polysilicon layer 18 includes a source region 18s, a drain region 18d, and a channel region 18c therebetween.

The buffer layer 14, the polysilicon layer 18, and the gate insulating layer 20 are covered by an ILD 24. A first contact hole h1 and a second contact hole h2 are formed in the ILD 24 so as to expose the source region 18s and the drain region 18d, respectively. A first electrode 26 and a second electrode 28 are formed on the ILD 24 so as to fill the first contact hole h1 and the second contact hole h2, respectively. The first electrode 26 and the second electrode 28 can be formed of the same material.

A method of manufacturing a TFT according to embodiments of the present invention will now be described.

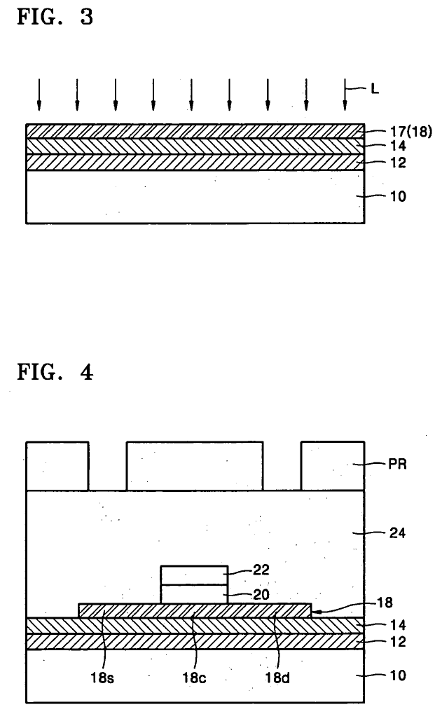

FIGS. 3 through 6 are cross-sectional views illustrating a method of manufacturing the top gate type TFT shown in FIG. 1.

Referring to FIG. 3, a thermal conductive layer 12 and a buffer layer 14 are sequentially stacked on a substrate 10. The substrate 10 is formed of plastic, for instance.

The thermal conductive layer 12 may be formed to a thickness of about 1000 Å using reactive sputtering. Here, the thermal conductive layer 12 can be formed of a transparent insulating layer having a high thermal conductivity, for example, an AlN layer.

The buffer layer 14 may be formed of, for example, a SiO₂ layer. In this case, the buffer layer 14 is formed to a thickness of about 2000 Å. The buffer layer 14 and the thermal conductive layer 12 formed of AlN prevent impurities contained in the substrate 10 from being diffused into members disposed on the buffer layer 14 and the AlN layer 12. Accordingly, if the thermal conductive layer 12 is formed of AlN, depositing the buffer layer 14 may be omitted. However, if the thermal conductive layer 12 is formed of a conductive material, the buffer layer 14 is required.

Thereafter, an amorphous silicon (a-Si) layer 17 is stacked on a predetermined region of the buffer layer 14 to a thickness of, for example, about 500 Å. The a-Si layer 17 can be formed using a predetermined deposition apparatus, such as a sputter apparatus or an apparatus for plasma-enhanced chemical vapor deposition (PECVD).

Thereafter, a laser beam L is irradiated by one-shot or multi-shot irradiation onto the entire surface of the a-Si layer 17 using a laser generator for emitting a laser beam L having a predetermined energy density of, for example, 100 to 150 mJ/cm². It is preferable that a XeCl eximer laser having a short pulse of about 10 ns and a wavelength of 308 nm be used as the laser generator, but other laser generators, such as Nd-YaG lasers, may be utilized instead.

When the laser beam L is irradiated onto the a-Si layer 17 as described above, amorphous silicon in the entire region of the a-Si layer 17 is crystallized into polysilicon due to heat energy of the laser beam L. During this reaction, heat generated at the a-Si layer 17 is rapidly exhausted through the thermal conductive layer 12 having the high thermal conductivity.

As a result, the a-Si layer 17 is transformed into a polysilicon layer 18 as shown in FIG. 3, and polycrystalline grains having a uniform size of about 60 nm are formed in the polysilicon layer 18. Since the polysilicon layer 18 is formed at a low temperature of about 25 to 150° C., the plastic substrate 10 can be used.

Referring to FIG. 4, the polysilicon layer 18 formed on the buffer layer 14 is patterned. Since the patterning of the polysilicon layer 18 is performed using a known method, a detailed description thereof will be omitted.

Thereafter, a gate insulating layer 20 and a gate electrode 22 are sequentially formed on the patterned polysilicon layer 18 and then patterned. Impurity ions are implanted into the polysilicon 18 by using the gate insulating layer 20 or the gate electrode 22 as an ion implantation mask. Then, a laser beam L is irradiated to activate a source region 18s and a drain region 18d. Here, the laser beam L is irradiated by one-shot or multi-shot irradiation using a laser generator for emitting a laser beam L having a predetermined energy density of, for example, 100 to 150 mJ/cm². It is preferable that a XeCl eximer laser having a short pulse of about 10 ns and a wavelength of 308 nm be used as the laser generator, but other laser generators, such as Nd-YaG lasers, may be utilized instead. As a result, ion doped regions in the polysilicon layer 18 become the source region 18s and the drain region 18d, respectively, and a channel region is formed between the source and drain regions 18s and 18d.

Thereafter, an ILD 24 is formed on the buffer layer 14 to cover the gate insulating layer 20, the gate electrode 22, and the polysilicon layer 18.

A photoresist pattern PR is formed on the ILD 24 so as to expose portions of the ILD 24, which correspond to the source region 18s and the drain region 18d of the polysilicon layer 18.

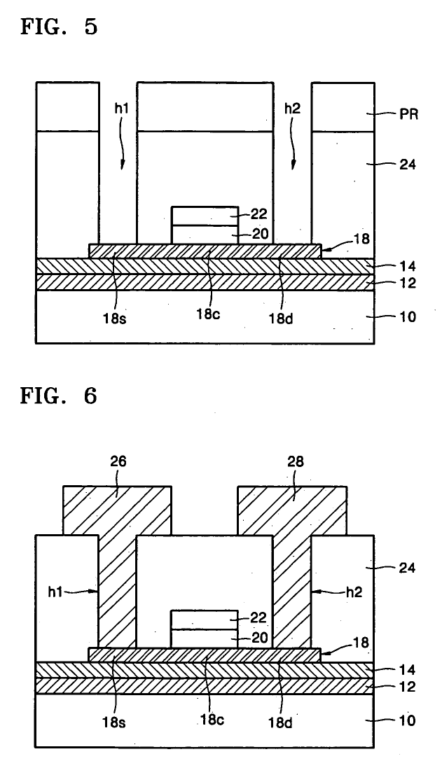

After the photoresist pattern PR is formed, as shown in FIG. 5, the exposed portion of the ILD 24 are etched using the photoresist pattern PR as an etch mask. This etch process is performed until the source region 18s and the drain region 18d are exposed. Thus, a first contact hole h1 exposing the source region 18s and a second contact hole h2 exposing the drain region 18d are formed in the ILD 24. Thereafter, the photoresist pattern PR is removed.

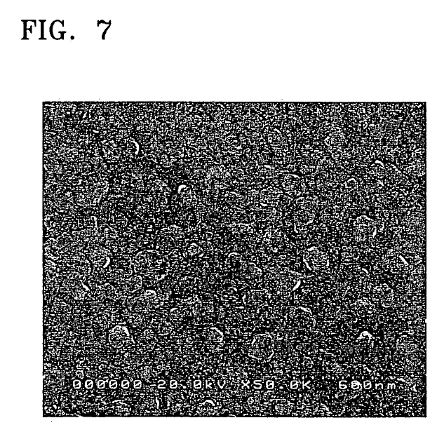

Referring to FIG. 6, a metal layer (not shown) is formed on the ILD 24 so as to fill the first and second contact holes h1 and h2. Then, the metal layer is patterned using photolithography and etch processes so that a first electrode 26 connected to the source region 18s and a second electrode 28 connected to the drain region 18d are formed.

FIG. 7 is a scanning electron microscope (SEM) photograph showing crystalline grains of a polysilicon layer that is formed by one-shot irradiation of an eximer laser beam having an energy density of about 140 mJ/cm² onto an amorphous silicon layer.

Referring to FIG. 7, it can be seen that polycrystalline grains are formed with a uniform size of about 60 nm. This is because heat produced by laser irradiation is exhausted through an AlN layer and thus, no local thermal reactions occurs.

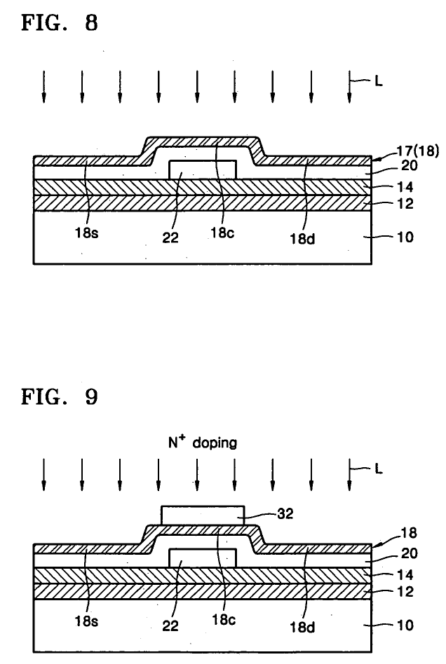

FIGS. 8 through 12 are cross-sectional views illustrating a method of manufacturing the bottom gate type TFT shown in FIG. 2.

Referring to FIG. 8, a thermal conductive layer 12 and a buffer layer 14 are sequentially formed on a substrate 10. The substrate 10 is formed of plastic.

The thermal conductive layer 12 may be formed to a thickness of about 1000 Å using reactive sputtering. Here, the thermal conductive layer 12 can be formed of a transparent insulating layer having a high thermal conductivity, for example, an AlN layer.

The buffer layer 14 may be formed of, for example, a SiO₂ layer. In this case, the buffer layer 14 is formed to a thickness of about 2000 Å. The buffer layer 14 and the thermal conductive layer 12 formed of AlN prevent impurities contained in the substrate 10 from being diffused into members disposed on the buffer layer 14 and the AlN layer 12. Accordingly, if the thermal conductive layer 12 is formed of AlN, depositing the buffer layer 14 may be omitted. However, if the thermal conductive layer 12 is formed of a conductive material, the buffer layer 14 is required.

Thereafter, a gate electrode 22 is formed on a predetermined region of the buffer layer 14.

A gate insulating layer 20 and an amorphous silicon layer 17 are sequentially deposited on the buffer layer 14 to cover the gate electrode 22. The a-Si layer 17 is stacked to a thickness of, for example, about 500 Å. The a-Si layer 17 can be formed using a predetermined deposition apparatus, such as a sputter apparatus and an apparatus for PECVD.

Thereafter, a laser beam L is irradiated by one shot or multi-shot irradiation onto the entire surface of the a-Si layer 17 using a laser generator for emitting a laser beam having a predetermined energy density of, for example, 100 to 150 mJ/cm². It is preferable that a XeCl eximer laser, having a short pulse of about 10 ns and a wavelength of 308 nm, be used as the laser generator, but other laser generators, such as Nd-YaG lasers, may be utilized instead.

When the laser beam L is irradiated onto the a-Si layer 17 as described above, as heat is generated in the entire region of the a-Si layer 17, amorphous silicon is crystallized into polysilicon. During this reaction, heat generated from the a-Si layer 17 is rapidly exhausted through the thermal conductive layer 12 having the high thermal conductivity. Also, the thermal conductive layer 12 makes thermal flow under the a-Si layer 17 uniform, thereby forming the polysilicon layer 18 having generally uniform crystalline grains.

As a result, the a-Si layer 17 is transformed into a polysilicon layer 18, and polycrystalline grains having a uniform size of about 60 nm are formed in the polysilicon layer 18. Since the polysilicon layer 18 is formed at a low temperature of about 25 to 150° C., the plastic substrate 10 can be used.

Referring to FIG. 9, a predetermined pattern, for example, a silicon oxide layer 32, is formed on a portion of the polysilicon layer 18 where a channel region will be formed.

Thereafter, n⁺ impurity ions are doped into the polysilicon layer 18 using the silicon oxide layer 32 as an ion implantation mask. A laser beam L is irradiated to activate a source region 18s and a drain region 18d. Here, the laser beam L is irradiated by one-shot or multi-shot irradiation using a laser generator for emitting a laser beam having a predetermined energy density of, for example, 100 to 150 mJ/cm². It is preferable that a XeCl eximer laser, having a short pulse of about 10 ns and a wavelength of 308 nm, be used as the laser generator, but other laser generators, such as Nd-YaG lasers, may be utilized instead. As a result, ion doped regions in the polysilicon layer 18 become the source region 18s and the drain region 18d, respectively, and a channel region 18c is formed between the source and drain regions 18s and 18d.

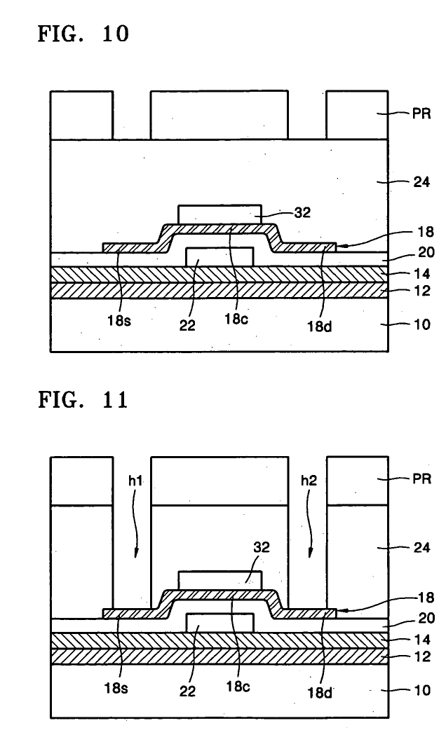

Referring to FIG. 10, the polysilicon layer 18 is patterned such that portions of the polysilicon layer 18 on both sides of the silicon oxide layer 32 remain. Since the patterning of the polysilicon layer 18 is performed using a known method, a detailed description thereof will be omitted. The patterning of the polysilicon layer 18 may be performed prior to the above-described ion implantation process.

Thereafter, an ILD 24 is formed on the gate insulating layer 20 to cover the polysilicon layer 18.

A photoresist pattern PR is formed on the ILD 24 so as to expose portions of the ILD 24, which correspond to the source region 18s and the drain region 18d of the polysilicon layer 18.

After the photoresist pattern PR is formed, as shown in FIG. 11, the exposed portion of the ILD 24 are etched using the photoresist pattern PR as an etch mask. This etch process is performed until the source region 18s and the drain region 18d are exposed. Thus, a first contact hole h1 exposing the source region 18s and a second contact hole h2 exposing the drain region 18d are formed in the ILD 24. Thereafter, the photoresist pattern PR is removed.

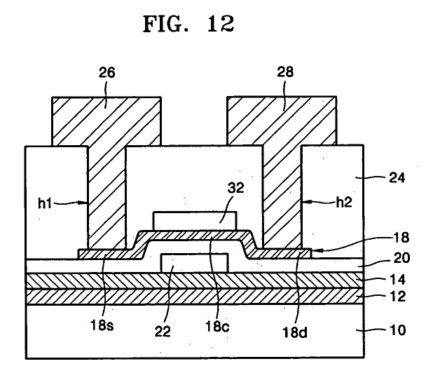

Referring to FIG. 12, a metal layer (not shown) is formed on the ILD 24 so as to fill the first and second contact holes h1 and h2. Then, the metal layer is patterned using photolithography and etch processes so that a first electrode 26 connected to the source region 18s and a second electrode 28 connected to the drain region 18d are formed.

As described above, in a TFT of the present invention, a polysilicon layer including uniform crystalline grains is formed on a plastic substrate, thereby improving field effect mobility.

Since an a-Si layer is crystallized at a low temperature using a laser, and a buffer layer for exhausting heat is formed of a high thermal conductive material, a TFT can be manufactured using a plastic substrate. A display panel including this TFT can easily exhaust heat produced by driving a device, thus enabling stable drive.

Also, the TFT of the present invention can employ a typical eximer laser or solid phase Nd-YaG laser. Accordingly, the present invention can utilize conventional manufacturing processes of TFTs.

Further, since a buffer layer is formed of a transparent high thermal conductive material (i.e., AlN), a TFT of the present invention can be applied to a reflection type FPD or a projection type FPD depending on purpose.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An electronic device comprising:
a plastic substrate;
a transparent thermal conductive layer stacked on the plastic substrate;
a polysilicon layer stacked on the thermal conductive layer; and
a functional device disposed on the polysilicon layer.

2. The device of claim 1, wherein the functional device is any one selected from the group consisting of a transistor, a light emitting device, and a memory device.

3. The device of claim 2, wherein the functional device is a thin film transistor comprising a gate stack stacked on the polysilicon layer.

4. The device of claim 3, further comprising a buffer layer disposed between the thermal conductive layer and the polysilicon layer.

5. The device of claim 3, wherein the thermal conductive layer is formed of aluminum nitride (AlN).

6. An electronic device comprising:
a plastic substrate;
a transparent thermal conductive layer stacked on the plastic substrate;
a functional device disposed over the thermal conductive layer; and
a polysilicon layer disposed on the functional device.

7. The device of claim 6, wherein the functional device is any one selected from the group consisting of a transistor, a light emitting device, and a memory device.

8. The device of claim 7, wherein the functional device is a thin film transistor comprising:
a gate electrode disposed on the thermal conductive layer; and
a gate oxide layer disposed on the thermal conductive layer to cover the gate electrode.

9. The device of claim 6, further comprising a buffer layer disposed between the thermal conductive layer and the gate electrode.

10. The device of claim 8, wherein the thermal conductive layer is formed of aluminum nitride (AlN).

11. A method of manufacturing an electrode device, the method comprising:
forming a transparent thermal conductive layer on a plastic substrate;
forming an amorphous silicon layer on the thermal conductive layer;
transforming the amorphous silicon layer into a polysilicon layer; and
forming a functional device on the polysilicon layer.

12. The method of claim 11, wherein the functional device is any one selected from the group consisting of a transistor, a light emitting device, and a memory device.

13. The method of claim 12, wherein the functional device is the thin film transistor, and the forming of the functional device comprises forming a gate stack on the polysilicon layer.

14. The method of claim 13, further comprising forming a buffer layer disposed between the thermal conductive layer and the polysilicon layer.

15. The method of claim 14, wherein the thermal conductive layer is formed of AlN.

16. The method of claim 11, wherein the transforming of the amorphous silicon layer into the polysilicon layer is performed by irradiating a laser beam having a predetermined energy density onto the amorphous silicon layer.

17. A method of manufacturing an electronic device, the method comprising:
forming a transparent thermal conductive layer on a plastic substrate;
forming a functional device on the thermal conductive layer;
forming an amorphous silicon layer over the functional device; and
transforming the amorphous silicon layer into a polysilicon layer.

18. The method of claim 17, wherein the functional device is any one selected from the group consisting of a transistor, a light emitting device, and a memory device.

19. The method of claim 18, wherein the functional device is the thin film transistor,
wherein the forming of the functional device comprises:
forming a gate electrode on the thermal conductive layer;
patterning the gate electrode; and
forming a gate insulating layer on the thermal conductive layer to cover the patterned gate electrode,
and wherein the forming of the amorphous silicon layer comprises forming the amorphous layer on the gate insulating layer.

20. The method of claim 19, further comprising forming a buffer layer between the thermal conductive layer and the gate electrode.

21. The method of claim 19, wherein the thermal conductive layer is formed of AlN.

22. The method of claim 19, wherein the transforming of the amorphous silicon layer into the polysilicon layer is performed by irradiating a laser beam having a predetermined energy density onto the amorphous silicon layer.
